(19) United States
(12) Patent Application Publication
(10) Pub. No.: US 2008/0158842 A1
(43) Pub. Date: Jul. 3, 2008

(54) STRESS AND COLLAPSE RESISTANT INTERCONNECT FOR MOUNTING AN INTEGRATED CIRCUIT PACKAGE TO A SUBSTRATE

(75) Inventor: Leon Stiborek, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/617,895

(22) Filed: Dec. 29, 2006

(51) Int. Cl. H05K 7/00; H05K 1/00; H01L 21/58

(52) U.S. Cl. 361/783; 174/258; 438/106

(57) ABSTRACT

A contact grid array interconnect element for mounting an IC package to a substrate. The interconnect comprises an insulating stand-off post having opposing ends. An electrically conductive core is embedded in and traverses the post. Conductive endplates are located on the opposing ends of the post and contact the core.

### TECHNICAL FIELD

The invention is directed to interconnect structures for mounting integrated circuit packages to substrates, as well as electrical devices and methods of manufacturing electrical devices that comprise such interconnects.

### BACKGROUND

As integrated circuit (IC) packages increase in complexity and density it is becoming increasingly difficult to mount the package to a substrate (e.g., a printed circuit board, PCB). For instance, interconnections that comprise a solder ball grid array (BGA) can collapse from the weight of certain IC packages, thereby reducing the desired stand-off between the IC package and the PCB. A reduction in the stand-off, in turn, can reduce the reliability of the IC. Simply increasing the size of the individual solder balls may not be satisfactory because this increases the lateral space occupied by the balls, thereby lowering the pitch density of the interconnections. The replacement of solder BGAs with a solder column grid array (CGA), or a pin array, can be also be problematic because such structures are fragile and particularly sensitive to fracture when subjected to mechanical or thermal stresses. The replacement of solder BGAs with metal-coated plastic balls can also be problematic because the thin outer metallic coating are fragile and have limited current-carrying capacity.

Accordingly, what is needed in the art is an interconnect structure that is stress and collapse resistant and a method of manufacturing thereof.

### SUMMARY

The invention provides in one embodiment a contact grid array interconnect element for mounting an IC package to a substrate. The interconnect comprises an insulating stand-off post having opposing ends and a conductive core embedded in and traversing the post. The interconnect also comprises conductive endplates located on the opposing ends of the post and contacting the core.

Another embodiment is an electrical device comprising an IC package, a substrate and a contact grid array of the above-described interconnects that couple the IC package to the substrate.

Still another embodiment is a method of manufacturing an electrical device. The method comprises fabricating an interconnect. The method also comprises mounting an array of the interconnects to an IC package and connecting the IC package to a substrate via said array of interconnects. Fabricating the interconnect includes embedding an electrically conductive core in an insulating stand-off post wherein the core traverses the post. Fabricating the interconnect also includes connecting electrically conductive endplates to opposing ends of the post, wherein each of the endplates contact one end of the core.

### DRAWINGS

The invention is described with reference to example embodiments and to accompanying drawings, wherein:

FIG. 1A presents a cross-sectional view of an example interconnect of the invention;

FIG. 1B presents a plan view of an example interconnect shown in FIG. 1A through view B-B;

FIG. 2 presents a cross-sectional view of an example electrical device of the invention; and

FIG. 3 presents a flow diagram of an example method of manufacturing an electrical device of the invention.

### DETAILED DESCRIPTION

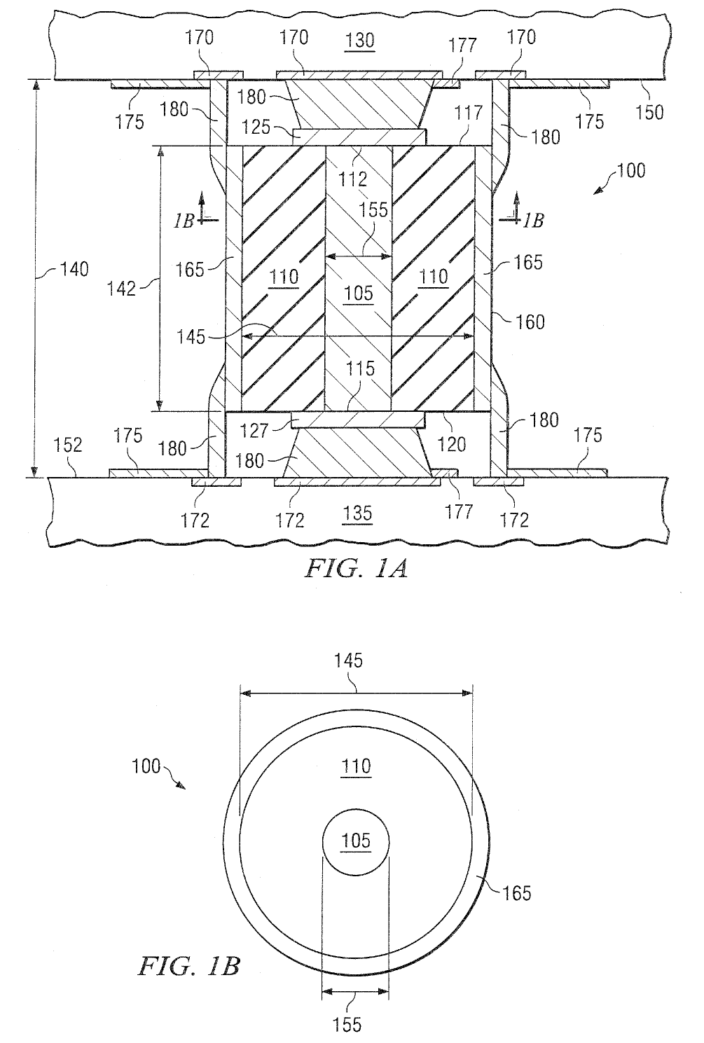

One embodiment of the invention is an interconnect that is an element of a contact grid array for mounting an IC package to a substrate. FIG. 1A presents a cross-sectional view of an example interconnect 100. FIG. 1B presents a plan view B-B of the example interconnect shown in FIG. 1A. The interconnect 100 comprises an electrically conductive core 105 and an insulating stand-off post 110. The core 105 and post 110 are configured to have improved resistance to stress and collapse. The arrangement of the core 105 and insulator 110 allow large current loads to be transmitted through the interconnect 100 while still tolerating greater thermal and mechanical stresses as compared to similar-dimensioned interconnects of BGA, CGA or pin arrays.

The electrically conductive core 105 is embedded, that is, contained within, the post 110, with the core 105 traversing the post 110. In some embodiments, the core 105 is surrounded by the insulating structure 110, except for the core's ends 112, 115, which are on opposing ends 117, 120 of the post 110.

The interconnect 100 further includes electrically conductive endplates 125, 127 located on the opposing ends 117, 120. Each of the endplates 125, 127 contact one of the ends 112, 115. In some cases, the endplates 125, 127 are discrete structures that are isolated from each other. E.g., the endplates 125, 127 are not part of a body that physically links the endplates together. The post 110 and core 105 are between and isolate the endplates 125, 127 from each other. It is desirable for the ends 117, 120 to have conductive endplates 125, 127 to facilitate making an electrical connection to both an IC package 130 and a substrate 135 (e.g., a PCB). The endplates 125, 127 also facilitate attachment of the interconnect 100 to the IC package 130 and substrate 135 via e.g., a solder or braze. In other cases, however, interconnects 100 can be attached to the IC package and substrate 130, 135 via epoxy or other adhesives.

The term insulating stand-off post as used herein refers to a discrete insulating structure that is not in contact with other such insulating structures and that helps to set and maintain the desired stand-off 140 between the IC package 130 and the substrate 135. In some embodiments, the post 110 has a long axis 142 and short axis 145, and the core 105 traverses the long axis 142. In such cases, the long axis 142 of the post 110 is perpendicular to a mounting surface 150 of the IC package 130, or to a mounting surface 152 of the substrate 135.

In certain embodiments, a ratio of the long axis 142 to the short axis 145 of the post 110 ranges from about 1.5:1 to 5:1, and in other cases, from about 1.5:1 to 3:1. This range of ratios provides a desirable balance within the interconnect 100. It provides a stable interconnect that is not prone to displacement when subject to e.g., lateral stress and that has a minimal surface area that an array of interconnects will occupy on the mounting surfaces of 150, 152 or substrate 135. At the same time, it provides an interconnect that maintains the desired stand-off 140 between the IC package 130 and the substrate 135.

In some embodiments, the length of the short axis 145 ranges from about 0.3 to 0.5 mm, and the long axis 142 ranges from about 0.5 to 2.5 mm, and in some cases from about 0.5 to 0.6 mm. However, in other embodiments the length of the long axis 142 ranges from about 0.1 to 2 mm, and in some cases from about 0.1 to 1 mm. The length of the long axis 142 is carefully selected so that the stand-off 140 is optimally balanced between avoiding too high a vertical profile and having a stand-off 140 that is sufficient to avoid IC reliability. Factors that affect the decision to have a certain stand-off include concerns that an insufficient stand-off 140 can result in diminished reliability, while an excessive stand-off 140 can result in an unsupported package to board structure, where forces from attached heat sinks or vibration can occur.

In some embodiments, the core 105 has a diameter 155 that ranges from about 0.1 to 0.3 mm. This diameter is conducive to passing a current in the range of about 0.1 to 5 Amps. The diameter 155 can be adjusted to other values as need to facilitate the conduction of larger or smaller currents between the IC package 130 and the substrate 135.

In some embodiments of the interconnect 100 the post 110 is cylindrically shaped. A cylindrically-shaped post 110 can be advantageous because it lends itself to being handled by mass sorting and assembly tools. E.g., a cylindrically-shaped post 110 can be rolled or vibrated into a sorting tray or tube to facilitate the transport of post 110 to an assembly tool, or to properly orient of assembled interconnect 100 relative to the IC package 130 or substrate 135 before being mounted to such structures. Some advantages in having posts of a particular shape include circular posts 110 lending to easier manufacturing, or other shapes, such as trapezoids or rectangles, maximizing one or more of support, packing density or increase current carrying capability for staggered interconnects 100.

In some embodiments of the interconnect 100, an outer surface 160 of the insulating structure 110 includes an electrically conductive layer 165. In some cases the layer 165 is configured to facilitate attachment of the interconnect 100 to one or both of the IC package 130 or substrate 135. The endplates 125, 127 or the layer 165 can be coupled to landing pads 170 of the IC package 130, or landing pads 172 of the substrate 135, using an adhesive 180 such as solder, braze or epoxy.

In some cases, the layer 165 is electrically isolated from the core 105 and the endplates 125, 127. This is desirable in instances when the layer 165 is configured to couple the IC package 130 to ground lines 175 on the IC package 130 or the substrate 135, while the core 105 is configured to couple the IC package 130 to communication lines 177 on the IC package 130 or substrate 135. The communication lines 177 can be coupled to other components of an electrical device (e.g., another IC component, amplifier, memory, etc. . . . ) that the IC package 130 and substrate 135 are part of.

In some cases, the layer 165 is co-axial with the core 105 and traverses the post 110. A co-axial arrangement can be advantageous in instances where the layer 165 serves as a ground connection. Interconnects 100 comprising a coaxial core 105 and outer conductive layer 165 advantageously minimizes the area occupied by the interconnect 100 on the IC package 130 or substrate 135. This, in turn, permits a higher pitch density of an array of interconnects 100 on the mount surfaces 150, 152 of the substrate 135 or IC package 130. In some cases, to maximize current flow, or to facilitate attachment to other structures 130, 135, is it desirable for the entire outer surface 160 of the post 110, except for its ends 117, 120, to be covered by the conductive layer 165.

While the post 110 can be composed of any insulating material, it is preferable that a flexible insulating material be used. A flexible post 110 helps to make the interconnect 100 more resistant to damage due to mechanical or thermal stress. Example materials include flexible organic polymers such as silicone, butadiene, polyimide or polysulphone rubbers or mixtures thereof, or other thermoplastics well known to those skilled in the art. Thermoplastics have the added advantage of being easily moldable or extrudable, and therefore can be inexpensively and simply formed into the post 110.

In some embodiments the post 110 is composed of a thermoplastic having a melting point of about 260° C. or higher, and more desirably 300° C. of higher. The use of such thermoplastics is advantageous when using high melting point solders, such as lead-free solders. The use of lead-free solders to connect the interconnect 100 to the IC package 130 or substrate 135 is desirable for meeting certain environmental or safety standards for the fabrication of electrical devices.

While the core 105 can be composed of any conductive material, it is preferable to use a flexible material. Some embodiments of the core 105 comprise a ductile metal, e.g., a metal. Example ductile metals include copper, silver, gold, nickel, palladium or alloys thereof. However, less ductile metals, e.g., tungsten, or non-metal conductors, e.g., graphite, can also be used. In some embodiments the core 105 comprises strands of metal wires that are braided together. A core 105 comprising braided wire advantageously has greater electrical conductivity and ductility, as compared to a core 105 comprising a unitary solid wire of similar diameter and composition.

The electrically conductive endplates 125, 127 and the layer 165 can comprise the same or different materials as the core 105. In some embodiments, the endplates 125, 127 comprises an under bump metallization (UBM) stack to facilitate adhesion of solder to the interconnect 100 and to the IC package 130 or substrate 135. The UBM stack can comprise two or more layers of Ti, W, Cr, Cu, or other metals well known to those skilled in the art, to facilitate adhesion to solder bumps 180 composed of PbSn, SnAgCu, Au or other types solder.

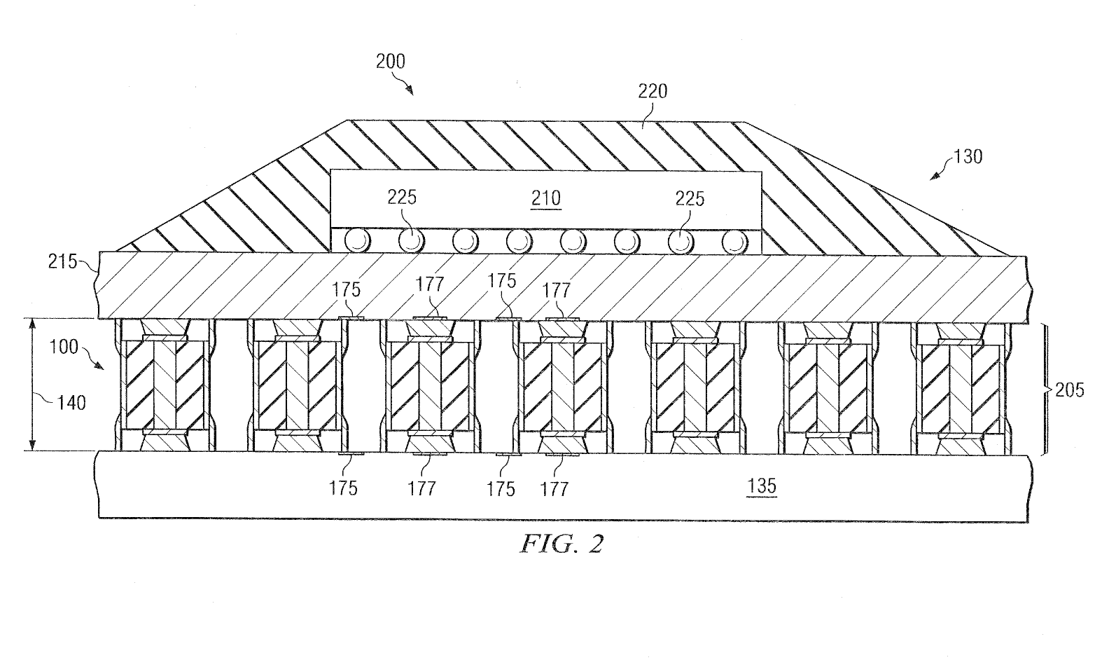

Another embodiment of the invention is an electrical device. FIG. 2 shows a cross-sectional view of an example electrical device 200. The device 200 (using the same reference numbers as in FIGS. 1A-1B) comprises an IC package 130, a substrate 135 and contact grid array 205 of interconnects 100 that couple the IC package 130 to the substrate 135. The array 205 could also include conventional interconnect structures such as solder balls, if desired. In some embodiments, however, it is desirable for the array 205 to be composed entirely of the interconnect 100, because this maximizes resistance to stress-induced changes in the stand-off 140.

The IC package 130 can comprise a semiconductor device 210, mounting pad 215, insulating housing 220, and other components well known to those skilled in the art. The semiconductor device 210 can comprise one or a plurality of integrated circuits, or other electrical components that are intended to work together. Examples include power amplifiers, Surface Acoustic Wave (SAW) filters, flash or static random access memory devices, inductors or capacitors. The semiconductor device 210 can be coupled to the connective structures of the pad 215 by conventional interconnect structures well known to those skilled in the art. E.g., an intra-package array of interconnects 225, such as a BGA or CGA may be used to connect the device 200 to the pad 215. The housing 220 can comprise insulating materials, such as a ceramic or epoxy material that is, e.g., injection molded around the device 210. The housing 220 around the device 210 is typically molded into a square or rectangular block.

Any of the above-described embodiments of the interconnects 100 can be incorporated into the array 205 of the electrical device 200. E.g., each of the interconnects 100 include an electrically conductive core 105 embedded in an insulating stand-off post 110 having opposing ends 117, 120, and electrically conductive endplates 125, 127 (FIGS. 1A-1B). As shown for the embodiment in FIGS. 1A-1B, one of the endplates 125 contacts the IC package 130 and the other endplate 127 contacts the substrate 135.

In some embodiments, an outer surface 160 of the post 110 includes an electrically conductive layer 165 (FIGS. 1A-1B). The layer 165 can be configured to couple the IC package 130 to a ground line 175 via landing pads 172 on the substrate 135, while the core 105 is configured to couple landing pads 170 of the IC package 130 to communication lines 177 on the substrate 135. The communication lines 177 are configured to send information between the semiconductor device 210 of the package 130 and other components of the device 200 (FIG. 2).

It is preferable for each of the interconnects 100 to be discrete structures. Independent free-standing interconnects 100 are desirable because they are less prone to damage when exposed to the stresses associated with a thermal cycle, as compared to e.g., interconnects that are part of a continuous sheet of material, such as a PCB. Interconnects that are part of a continuous sheet are more prone to fracture during thermal cycle than discrete interconnects because they have a more limited number of dimensions in which to expand or contract. One consequent advantage with using discrete interconnects is that a greater mismatch between the thermal expansion coefficients (CTEs) of the interconnect 100, substrate 135, and IC package 130 can be tolerated. This, in turn, allows a broader range of materials to be used to fabricate these structures. E.g., in some cases a 30 ppm difference between the package and interconnect substrate can be accommodated when using discrete interconnects.

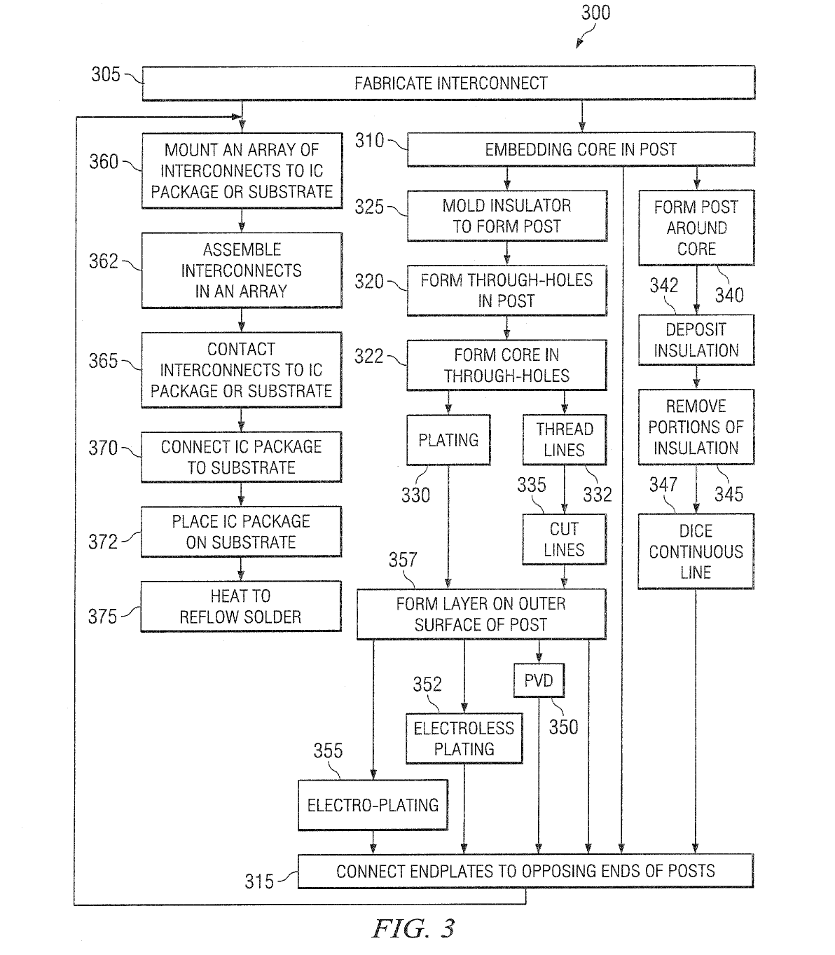

Another embodiment is a method of manufacturing an electrical device. FIG. 3 presents a flow diagram of an example method 300 of manufacturing an electrical device of the invention.

The method 300 includes fabricating an interconnect of the invention (step 305). Fabricating the interconnect includes a step 310 of embedding an electrically conductive core in an insulating stand-off post. As discussed above in the context of FIGS. 1 and 2, the core traverses the post. Fabricating the interconnect also includes a step 315 of connecting electrically conductive endplates on opposing ends of the post. As also discussed above in the context of FIGS. 1 and 2, each of the endplates contact one end of the core.

Some embodiments of embedding the core in the post (step 310) include a step 320 of forming a through-hole in the post and a step 322 of locating the core in the through-hole. E.g., an insulating material (e.g., a thermoplastic) can be molded in step 325 into the desired shape of the post (e.g., a cylindrical post) and then in step 320 a hole is punched through the post by mechanical or laser drilling. In some cases it is desirable to connect the endplate (step 315) after forming the through-hole (step 320), because then it is not necessary to drill or punch through e.g., a metal endplate.

In some cases the step 322 of locating the core in the through-hole comprises a plating step 330, where e.g., a metal is plated in the through-hole via e.g., an electroless plating process. In other cases the step 322 of locating the core comprises mechanically threading in step 332 a continuous line of the core material (e.g. a braided or solid wire) into the through-hole, followed by a step 335 of cutting the continous line to removing amounts of the line of core material that are outside of the opposing ends of the post.

In other embodiments, embedding the core in the post (step 310) includes a step 340 of forming the post around a continuous line of the conductive core material (e.g., a braided or solid wire). E.g., an insulating material, such as a thermoplastic, can be melted and coated or otherwise deposited (step 342) around discrete portions of the line or around the entire line. Portions of the insulating material can then be removed (step 345) such that portions of the continuous line of the core material are exposed and the posts formed. The line can then be diced (step 347) to form discrete interconnects. The dicing step 347 can be done before or after connecting the endplates to portions of the core that are not embedded in the insulating structure (step 315).

In some cases, connecting the endplates (step 315) includes a physical vapor deposition (PVD) step 350, e.g., sputtering, or an electroless plating step 352, to locate a metal onto the ends of the core the protrude from the post. In some cases, a combination of both steps 350, 352 are done. E.g., a seed layer of the endplate material is sputtered onto the end of the core, followed by electroless plating. In other embodiments, such as when a continuous line of core is used, an electroplating step 355 is performed to deposit the endplate material onto exposed portions of the core located between the posts. E.g., a current can be passed through the core to facilitate electrochemical deposition of a metal onto those portions of the core that are not covered by the posts. Connecting the endplates (step 315) can also include depositing an adhesive on the endplate.

Fabricating the interconnect 305 can further include a step 357 of forming an electrically conductive layer on an outer surface of the post. E.g., a metal layer can be deposited on the outer surface of the post by sputtering, plating, or a combination thereof such as described in steps 350, 352, or 355. As discussed in the context of FIGS. 1A-1B, the electrical layer (e.g., layer 165 in FIGS. 1A-1B) can be coaxial with the core (e.g., core 105 in FIGS. 1A-1B).

The method of manufacturing an electrical device 300, also comprises a step 360 of mounting an array of the interconnects fabricated in step 305 to one of an integrated circuit package or a substrate. Mounting the array can include assembling (step 362) an array of interconnects by using robotic tools to pick up individual or sets of interconnects and place them on the IC package. To facilitate assembling the interconnects into an array, it is sometimes desirable to use a stencil having openings that the interconnects uniquely fit into such that they are properly spaced apart and oriented relative to the IC package. E.g., the interconnects can be placed on the surface of the stencil and then vibrated until the interconnects fall into the openings. The assembled array of interconnects is then contacted to one of the IC package or the substrate in step 365. The use of an adhesive on the endplates, e.g., epoxy, a solder paste or flux, can help to keep the interconnects in place once they contact the IC package or substrate.

The method 300 of manufacturing the electrical device further comprises a step 370 of connecting the other of the IC package or substrate via the array of interconnects that were mounted to the IC package or substrate in step 365. E.g., the connecting step 370 can include using robotic tools to contact (step 372) the IC package with its attached array of interconnects on the substrate such that the array of interconnects contacts the substrate. Again, an adhesive on the endplates of the interconnects can help to keep the interconnect array in place once it contacts the substrate. In some instances, such as when the adhesive is epoxy, it is sufficient to simply contact the IC package to the substrate. In other instances, connecting the IC package to the substrate can further include a heating step 375 to reflow solder on the interconnects, IC package, substrate and thereby bonding the IC, interconnects and substrate together.

Although the present invention has been described in detail, those skilled in the art should understand that they could make various changes, substitutions and alterations herein without departing from the scope of the invention in its broadest form.

1. A contact grid array interconnect element for mounting an integrated circuit package to a substrate, comprising:
an insulating stand-off post having opposing ends;
a conductive core embedded in and traversing said post; and
conductive endplates located on said opposing ends of said post and contacting said core.

2. The interconnect of claim 1, wherein said endplates are discrete structures that are isolated from each other.

3. The interconnect of claim 1, wherein said core traverses a long axis of said post.

4. The interconnect of claim 1, wherein said post is cylindrically-shaped.

5. The interconnect of claim 1, wherein an outer surface of said post includes an electrically conductive layer.

6. The interconnect of claim 5, wherein said layer is electrically isolated from said core and said endplates.

7. The interconnect of claim 5, wherein said layer is co-axial with said core and traverses said post.

8. The interconnect of claim 5, wherein said entire outer surface of said post is covered by said layer, except for said ends.

9. The interconnect of claim 1, wherein said post is composed of a thermoplastic having a melting point of about 260° C. or higher, and said core comprises a ductile metal.

10. An electrical device, comprising:
an IC package;
a substrate; and
a contact grid array of interconnects that couple said IC package to said substrate, wherein said each of said interconnects include:
an insulating stand-off post having opposing ends;
a conductive core embedded in and traversing said post; and
conductive endplates located on said opposing ends of said post and contacting said core.

11. The device of claim 10, wherein one of said endplates contacts said IC package and the other of said endplates contacts said substrate.

12. The device of claim 10, wherein each of said interconnects are discrete structures.

13. The device of claim 10, wherein an outer surface of said post includes an electrically conductive layer.

14. The device of claim 13, wherein said layer is configured to couple said IC package to a ground line on said substrate, and said core is configured to couple landing pads of said IC package to conductive lines on said substrate.

15. A method of manufacturing an electrical device, comprising:
fabricating an interconnect, including:
embedding an electrically conductive core in an insulating stand-off post, wherein said core traverses said post; and
connecting conductive endplates to opposing ends of said post, wherein each of said endplates contact one end of said core;
mounting an array of said interconnects to one of an IC package or a substrate; and
connecting said one IC package or said substrate to the other of said IC package or said substrate through said array of interconnects.

16. The method of claim 15, wherein said embedding includes forming a through-hole in said post and locating said core in said through-hole.

17. The method of claim 16, wherein said locating includes plating a metal in said through-hole.

18. The method of claim 15, wherein said embedding includes forming said post around a continuous line of said conductive core.

19. The method of claim 15, wherein said connecting includes sputtering or plating a metal onto ends of said core.

20. The method of claim 15, further including forming an electrical layer on an outer surface of said post.
